(19) United States
(12) Patent Application Publication
(10) Pub. No.: US 2020/0107478 A1
(43) Pub. Date: Apr. 2, 2020

(54) HOUSING AND ELECTRONIC APPARATUS HAVING THE SAME

(71) Applicant: BOE TECHNOLOGY GROUP CO., LTD., Beijing (CN)

(72) Inventors: Ken WEN, Beijing (CN); Deli FANG, Beijing (CN); Yongda MA, Beijing (CN); Jian XU, Beijing (CN)

(21) Appl. No.: 16/425,108

(22) Filed: May 29, 2019

(30) Foreign Application Priority Data
Sep. 30, 2018 (CN) 201821621803.9

(51) Int. Cl. H05K 9/00; H05K 1/02; H01Q 1/22; G06F 1/16; G06F 1/18

(52) U.S. Cl. CPC H05K 9/0037; H05K 1/0243; G06F 1/182; H01Q 1/2283; G06F 1/1698; H01Q 1/2266

(57) ABSTRACT

A housing and an electronic apparatus having the housing are disclosed. The housing includes a shielding component and an insulating component fixedly connected with the shielding component; the insulating part is configured to arrange an antenna.

### TECHNICAL FIELD

Embodiments of the present disclosure relate to a housing and an electronic apparatus having the same.

### BACKGROUND

An electronic apparatus such as display apparatus usually includes a rear housing and an electromagnetic shielding component which is disposed separately. An antenna may be provided inside the rear housing so as to receive a signal.

### SUMMARY

On one aspect, an embodiment of the present disclosure provides a housing, including: a shielding component and an insulating component fixedly connected with the shielding component; the insulating part is configured to arrange an antenna.

In an example, the shielding component is provided with a through hole penetrating the shielding component, and the insulating component is provided at the through hole.

In an example, the through hole is configured to receive an antenna module including the insulating component and the antenna, and the shielding component is configured to have a thickness greater than or equal to a thickness of the antenna module.

In an example, the shielding component includes a first surface and a second surface opposite to each other; the shielding component is provided with a mounting hole, and the mounting hole includes a first hole part and a second hole part; the first hole part is concaved from the first surface towards the second surface of the shielding component to form an abutting surface, the second hole part penetrates both of the abutting surface and the second surface; the first hole part is configured to arrange the insulating component and the antenna, and the second hole part is configured such that a signal line connected with the antenna passes therethrough.

In an example, the first hole part is configured to receive an antenna module including the insulating component and the antenna, and the first hole part is configured to have a thickness greater or equal to a thickness of the antenna module.

In an example, the insulating component includes a supporting part and a protecting part; one surface of the supporting part is concaved to form an accommodating part with an opening, the accommodating part is configured to receive the antenna; the supporting part is configured such that the signal line passes therethrough to be in contact with the second surface of the shielding component.

On the other aspect, an embodiment of the present disclosure provides an electronic apparatus, including a housing and an antenna; the housing includes a shielding component and an insulating component fixedly connected with the shielding component, and the antenna is provided at the insulating part.

In an example, the shielding component is provided with a through hole penetrating the shielding component, and the insulating component is provided at the through hole.

In an example, an antenna module including the insulating component and the antenna is located inside the through hole, and a thickness of the antenna module is smaller than or equal to a thickness of the shielding component.

In an example, the antenna is connected with a signal line; the shielding component includes a first surface and a second surface opposite to each other, the shielding component is provided with a mounting hole, and the mounting hole includes a first hole part and a second hole part; the first hole part is concaved from the first surface towards the second surface of the shielding component to form an abutting surface, the second hole part penetrates both of the abutting surface and the second surface; the insulating component and the antenna are provided at the first hole part, and the signal line passes through the second hole part.

In an example, the antenna is located between the insulating component and the second hole part.

In an example, an antenna module including the insulating component and the antenna is located inside the first hole part, and a thickness of the antenna module is smaller than or equal to a thickness of the first hole part.

In an example, the insulating component includes a supporting part and a protecting part, one surface of the supporting part is concaved to form an accommodating part with an opening, the antenna is located on the supporting part and is located inside the accommodating part; the signal line passes through the supporting part to be in contact with the second surface of the shielding component; and the antenna is located between the protecting part and the supporting part.

In an example, the electronic apparatus includes a display module, at least one of the insulating component and the antenna is provided as a part of the display module.

In an example, the display module includes a display screen and an electrode; and at least part of the insulating component is provided as the display screen or is provided as at least part of the display screen.

In an example, the display module includes a display screen and an electrode; and at least part of the antenna is provided as the electrode or is provided as a part of the electrode or is located in a same layer with the electrode.

In an example, the housing is at least provided as a rear housing of the electronic apparatus.

In an example, the rear housing is provided with a protrusion part raised outwards with respect to an external surface of the rear housing, and an interior of the protrusion part is configured to receive one or more electronic element.

In an example, the protrusion part is provided with a heat dissipation hole.\

In an example, the electronic apparatus is a display apparatus.

### BRIEF DESCRIPTION OF THE DRAWINGS

Hereinafter, the drawings necessary for description of embodiments of the present disclosure are simply introduced in order to more clearly explain technical solution(s) of the embodiments of the present disclosure.

FIG. 1 is a structural diagram illustrating an electronic apparatus provided by an embodiment of the present disclosure;

FIG. 2 is an elevation view illustrating a housing of the electronic apparatus in FIG. 1;

FIG. 3 is a cross-sectional view illustrating the housing in FIG. 2;

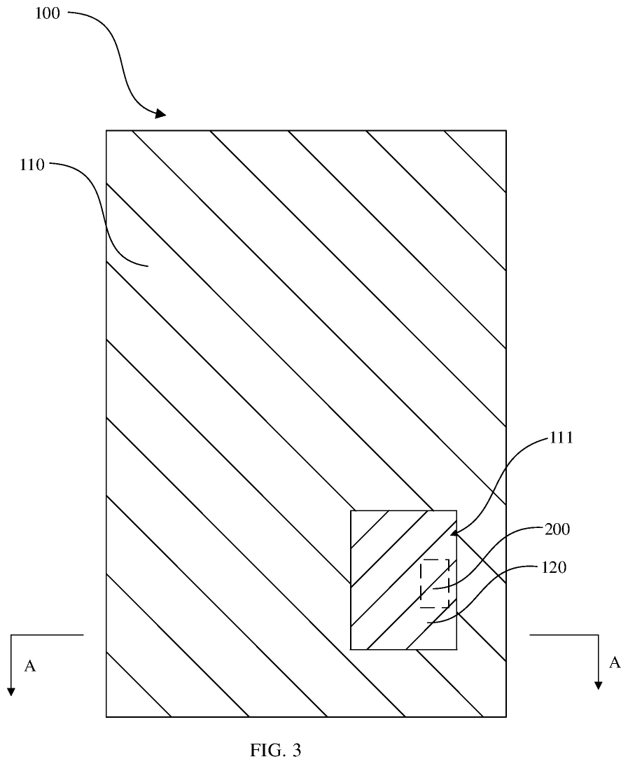

FIG. 4 is a cross-sectional view taken along A-A line in FIG. 3;

FIG. 5 is a cross-sectional view illustrating a housing in an electronic apparatus provided by another embodiment of the present disclosure;

FIG. 6 is a cross-sectional view illustrating a shielding component of a housing in an electronic apparatus provided by another embodiment of the present disclosure;

FIG. 7 is a cross-sectional view taken along B-B line in FIG. 6; and

FIG. 8 is a cross-sectional view illustrating the housing in FIG. 5 in which an insulating component and an antenna have been mounted.

### DETAILED DESCRIPTION

In order to make objects, technical details and advantages of the embodiments of the disclosure apparent, technical solutions according to the embodiments of the present disclosure will be described clearly and completely as below in conjunction with the accompanying drawings of embodiments of the present disclosure. Apparently, the described embodiments are only a part of but not all of exemplary embodiments of the present disclosure. Based on the described embodiments of the present disclosure, various other embodiments can be obtained by those of ordinary skill in the art without creative labor and those embodiments shall fall into the protection scope of the present disclosure.

Unless otherwise defined, the technical terminology or scientific terminology used herein should have the same meaning as commonly understood by one of ordinary skill in the art to which this disclosure belongs. Likewise, terms like “first,” “second,” etc., which are used in the description and the claims of the present application for disclosure, are not intended to indicate any sequence, amount or importance, but distinguish various components. The phrases “connect”, “connected”, etc., are not intended to define a physical connection or mechanical connection, but may include an electrical connection, directly or indirectly.

An embodiment of the present disclosure provides an electronic apparatus. The electronic apparatus herein can be a display apparatus with function of electronic display such as mobile phone, electronic watch and liquid crystal display.

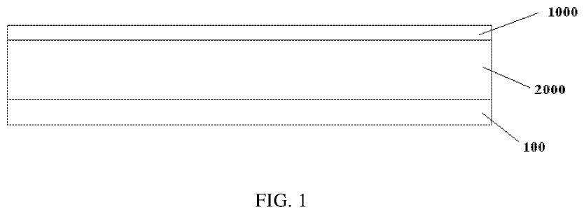

As illustrated in FIG. 1, the electronic apparatus provided by the present embodiment can include a display module 1000 and at least one housing 100. A receiving chamber 2000 can be defined by the housing 100 and the display module 1000. The receiving chamber 2000 can accommodate a plurality of electronic elements (not illustrated).

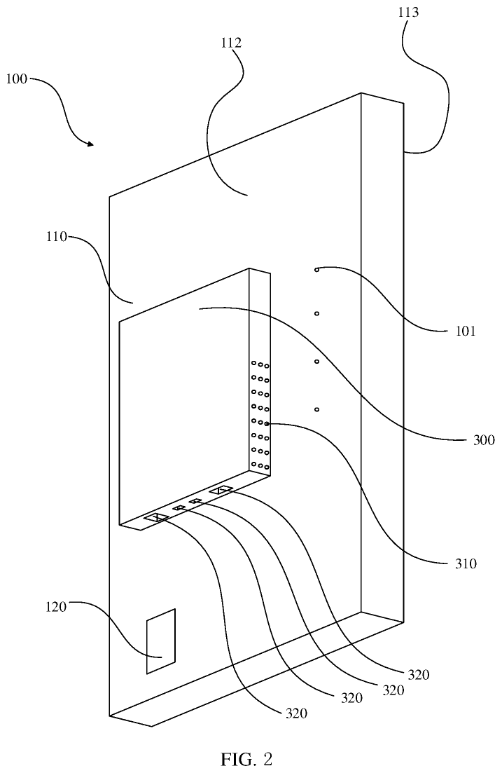

In the present embodiment, as illustrated in FIG. 2, the housing 100 can include an electrically conductive shielding component 110 and an insulating component 120. The insulating component 120 is fixed on the shielding component 110, and can be configured to arrange an antenna 200.

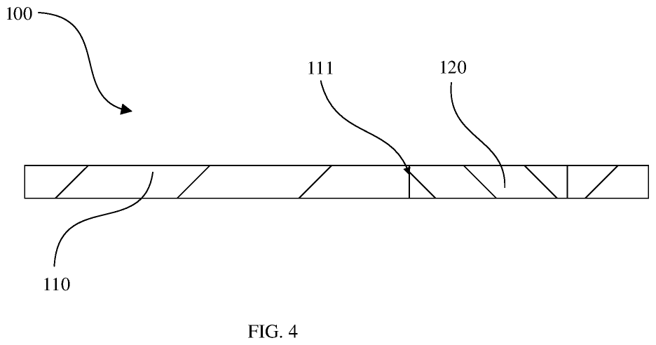

In the present embodiment, as illustrated in FIG. 2-FIG 4, the shielding component 110 is provided with a mounting hole 111, and the insulating component 120 is disposed inside the mounting hole 111. The antenna 200 is fixed at the insulating component 120 and is electrically insulated from the shielding component 110. The shielding component 110 can includes a first surface and a second surface opposite to each other. The first surface may be an external surface 112 of the shielding component 110 far away from the receiving chamber, and the second surface may be an internal surface 113 of the shielding component 110 closer to the receiving chamber. The mounting hole 111 can be a through hole which penetrates the internal surface 113 and the external surface 112 of the shielding component 110.

In an example of the present embodiment, the mounting hole 111 is a rectangular-shaped through hole which penetrates the internal surface 113 and the external surface 112. Of course, in other examples, the mounting hole 111 can also have any other shape such as cylindrical shape. By forming the mounting hole 111 into a through hole, a signal line connected to the antenna 200 can directly pass through the mounting hole 111 and reach the internal surface 113 of the shielding component 110, so that the antenna 200 can transmit and receive a signal inside or outside the shielding component 110 directly through the mounting hole 111 in a form of through hole and a mounting operation will be more convenient.

In an example of the present embodiment, the antenna 200 can be adhered onto a surface of the insulating component 120 far away from the receiving chamber, or the antenna 200 can be adhered onto a surface of the insulating component 120 closer to the receiving chamber. Of course, in other examples, an interior of the insulating component 120 can be provided with a cavity for accommodating the antenna 200 and the antenna 200 can be fixed inside the cavity, so as to achieve a connection between the insulating component 120 and the antenna 200. A material of the insulating component 120 can be an insulating material such as mylar piece, plastic and rubber.

In some other examples of the present embodiment, the shielding component 110 may not be provided with the mounting hole 111. For example, the shielding component 110 can further include several side surfaces connected with the first surface and the second surface of the shielding component 110, and the insulating component 120 can be adhered onto any of the side surfaces of the shielding component 110.

In the present embodiment, a material of the shielding component 110 can be a metallic material or an insulating material plated with a metallic layer. Of course, theoretically, the material of the shielding component 110 can be any other material which can play a role of shielding.

In the present embodiment, the antenna 200 is configured to receive a signal from the outside, and is electrically connected with element(s) disposed inside the receiving chamber through the signal line connected with the antenna 200, so as to feed a signal to the element(s) inside the receiving chamber. At the same time, the antenna 200 can also receive a signal from the element(s) inside the receiving chamber and transmit the signal to the outside through the signal line. The insulating component 120 can ensure that the antenna 200 would not be subjected to any interference from the shielding component 110. By arranging the antenna 200 in the shielding component 110, a lighter and thinner structure of the housing 100 can be achieved on the premise of ensuring a normal operation of the antenna 200, so as to facilitate a lighter and thinner structure of the electronic apparatus.

In the present embodiment, optionally, the insulating component 120 and the antenna 200, together, can constitute an antenna module to be mounted inside the mounting hole 111, and a thickness of the entire antenna module is smaller than or equal to a thickness of the shielding component 110. In this way, after mounting the antenna module into the mounting hole 111, a surface of the antenna module can be flush with or smoothly connected with a surface of the shielding component. In the present embodiment, the external surface 112 and the internal surface 113 of the shielding component 110 both are flat and even surfaces; an external surface of the antenna module is flush with the external surface 112 of the shielding component 110; and an internal surface of the antenna module is flush with the internal surface 113 of the shielding component 110. For example, the external surface of the antenna module herein refers to a surface of the antenna module far away from the receiving chamber, and the internal surface of the antenna module refers to a surface of the antenna module closer to the receiving chamber. Of course, in other examples where the external surface 112 or the internal surface 113 of the shielding component 110 is a curved surface, the internal surface of the antenna module is smoothly connected with the internal surface 113 of the shielding component 110, and the external surface of the antenna module is smoothly connected with the external surface 112 of the shielding component 110. With such arrangement, a flat and even surface or a smooth surface of the housing 100 can be maintained.

In the present embodiment, when the antenna 200 is fixed inside the insulating component 120, the external surface of the antenna module is the surface of the insulating component 120 far away from the receiving chamber, and the internal surface of the antenna module is the surface of the insulating component 120 closer to the receiving chamber. For example, as illustrated in FIG. 2 and FIG. 4, the surface of the insulating component 120 far away from the receiving chamber is flush with and connected with the external surface 112 of the shielding component 110, and the surface of the insulating component 120 closer to the receiving chamber is flush with and connected with the internal surface 113 of the shielding component 110. Alternatively, when the antenna 200 is disposed inside the mounting hole 111 and is located at the surface of the insulating component 120 far away from the receiving chamber, the surface of the insulating component 120 closer to the receiving chamber is flush with or smoothly connected with the internal surface 113 of the shielding component 110. Alternatively, when the antenna 200 is disposed inside the mounting hole 111 and is located at the surface of the insulating component 120 closer to the receiving chamber, the surface of the insulating component 120 far away from the receiving chamber is flush with or smoothly connected with the external surface 112 of the shielding component 110.

In the present embodiment, a firm and tight connection between the antenna module and the shielding component 110 can be achieved by an interference fit between the insulating component 120 and the mounting hole 111. Of course, a firm and tight connection between the antenna module and the shielding component 110 can also be achieved by an adhering connection or a snap-fitting connection between the insulating component 120 and the mounting hole 111.

In the present embodiment, optionally, the insulating component 120 and the antenna 200 can also serve as a part of the display module. For example, the display module can include a display screen, an electrode and the like. At least part of the insulating component 120 serves as the display screen of the display module or serves as at least part of the display screen. The display screen can be a glass panel or a transparent insulating layer. At least part of the antenna 200 can serve as the electrode of the display module, or can serve as a part of the electrode, or can be disposed in a same layer with the electrode. When the insulating component 120 and the antenna 200 serve as a part of the display module, additional element(s) can be omitted, which facilitates a lighter and thinner structure. Of course, it's also possible that only the insulating component 120 serves as a part of the display module, or, only the antenna 200 serves as a part of the display module.

In the present embodiment, optionally, the housing 100 can be further provided with a threaded hole 101 which serves as a passage through which a screw, a bolt or the like can be inserted. By using a locking structure such as the screw or the bolt, the housing can be locked with other housing(s) or structure(s) (e.g., the display screen).

In the present embodiment, optionally, the housing 100 can serve as a rear housing of the electronic apparatus. For example, as illustrated in FIG. 2, the rear housing is provided with a protrusion part 300 which is raised outwards with respect to an external surface of the rear housing, and an interior of the protrusion part 300 can receive one or more element. For example, the interior of the protrusion part 300 can be provided with a System-on-a-chip (SoC) board or a power source board. Of course, the interior of the protrusion part 300 can also be provided with only one of the SoC board and the power source board. By arranging part of elements inside the protrusion part 300 disposed an a surface of the housing which serves as the rear housing, the number of elements disposed inside the housing and inside the receiving chamber would be reduced, so that a thickness of the receiving chamber can be decreased appropriately. In this way, a thickness of the rear housing can be reduced, which facilitates a lighter and thinner structure of the electronic apparatus. Optionally, the protrusion part 300 can be provided with a plurality of holes 310 for heat dissipation or air venting. With such arrangement, heat generated by the elements located inside the protrusion part 300 during operation would be dissipated through the holes 310, so as to ensure a normal operation of the elements. Optionally, an external surface of the protrusion part 300 can also be provided with a signal terminal 320 for signal transmission. The signal terminal 320 for example can be a USB slot, an earphone jack, a HDMI slot or the like, and the signal terminal 320 can be disposed to be spaced from the hole 310.

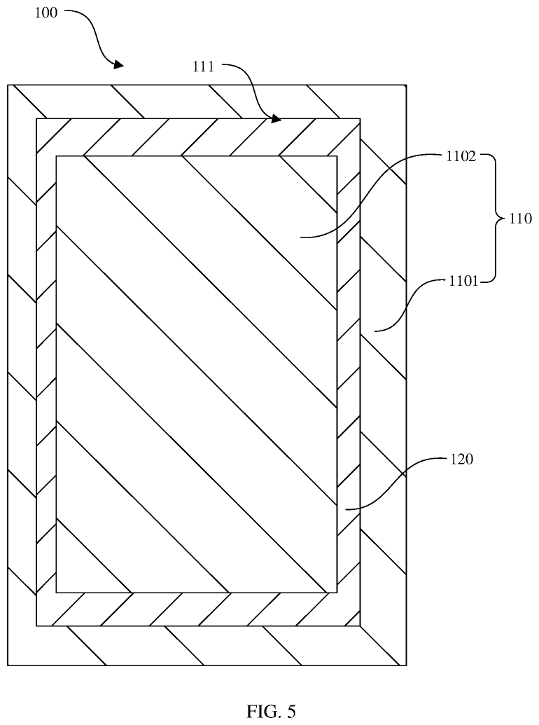

As illustrated in FIG. 5, another embodiment of the present disclosure further provides an electronic apparatus. The electronic apparatus provided by the present embodiment is substantially similar to the electronic apparatus describe with reference to FIG. 1-FIG 4, with the difference that, the mounting hole 111 provided in the shielding component 110 in the present embodiment is not a through hole in a rectangular shape or cylindrical shape or any other shapes. In the present embodiment, the mounting hole 111 is formed into an end-to-end annular structure, and the insulating component 120 is configured to have a shape matched with that of the mounting hole 111. In the present embodiment, as illustrated in FIG. 5, the shielding component 110 includes a first shielding part 1101 and a second shielding part 1102; the first shielding part 1101 is a hollowed structure which is sleeved outside the second shielding part 1102 and is spaced from the second shielding part 1102 so that a certain gap is formed there-between to serve as the mounting hole 111. That is to say, the mounting hole 111 is delimited by the first shielding part 1101 and the second shielding part 1102. The annular-shaped insulating component 120 is snap-fitted in the mounting hole 111. As illustrated in FIG. 5, the first shielding part 1101 is closely sleeved outside the insulating component 120; the insulating component 120 is closely sleeved outside the second shielding part 1102; and the first shielding part 1101, the insulating component 120 and the second shielding part 1102 form the housing 100. The first shielding part 1101, the insulating component 120 and the second shielding part 1102 are fixedly and firmly connected with each other by means of an interference fit, or by adhering, snap-fitting or integral forming. In order to clearly illustrate the positions and structures of the first shielding part 1101, the insulating component 120 and the second shielding part 1102 in the present embodiment, the antenna 200 is not illustrated in FIG. 5. The configuration of the antenna 200 can be referred to the foregoing embodiment without particularly described herein.

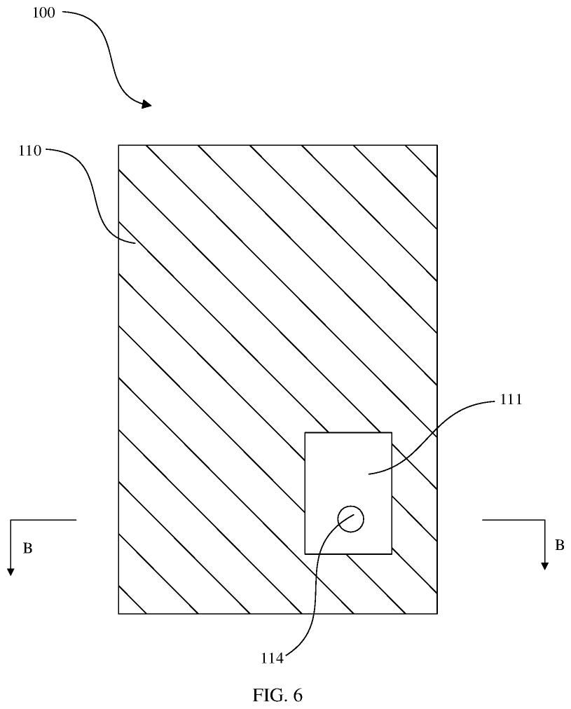

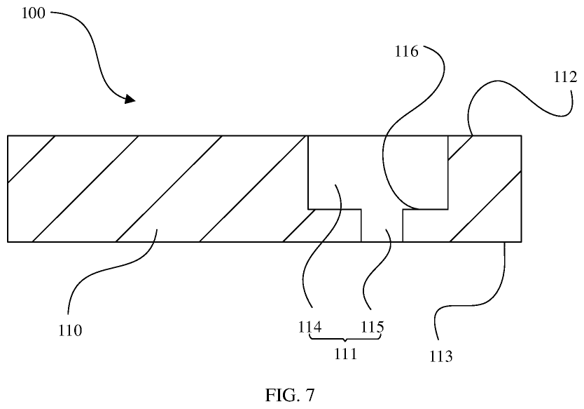

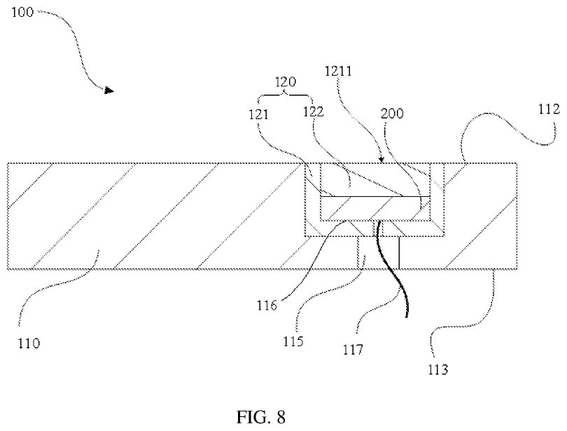

As illustrated in FIG. 6-FIG 8, yet another embodiment of the present disclosure further discloses an electronic apparatus. The electronic apparatus provided by the present embodiment is substantially similar to the electronic apparatus describe with reference to FIG. 1-FIG 4, with the difference that, the mounting hole 111 in the present embodiment includes a first hole part 114 and a second hole part 115 communicated with each other. As illustrated in FIG. 6, the first hole part 114 is concaved from the first surface 112 of the shielding component 110 towards the second surface 113; as illustrated in FIG. 7, the second hole part 115 extends from the second surface 113 of the shielding component 110 towards the first surface 112; furthermore, the first hole part 114 is communicated with the second hole part 115. For example, as illustrated in FIG. 7-FIG 8, the first hole part 114 is concaved from the external surface 112 of the shielding part 110 towards the internal surface 113 so as to form an abutting surface 116; the second hole part 115 penetrates the abutting surface 116 and the internal surface 113. In the present embodiment, as illustrated in FIG. 8, the antenna 200 is disposed between the insulating component 120 and the second hole part 115. The second hole part 115 can serve as a passage through which a signal line 117 connected to the antenna 200 can reach the internal surface 113 of the shielding component 110.

In the present embodiment, as illustrated in FIG. 8, the antenna 200 is fixed at the insulating component 120, abutted against the abutting surface 116 of the first hole part 114, and receives and transmits a signal through the signal line 117 disposed in the second hole part 115. In an example of the present embodiment, both of the first hole part 114 and the second hole part 115 are cylindrical-shaped holes, and a diameter of the second hole part 115 is smaller than a diameter of the first part 114. Of course, in other examples, the second hole part 115 can have any other shapes, as long as the second hole part 115 communicates the first hole part 114 with the receiving chamber and a size of the second hole part 115 is smaller than a size of the first hole part 114. The antenna 200 is disposed between the insulating component 120 and the second hole part 115; with such arrangement, the connection between the antenna 200 and the signal line 117 is facilitated.

In the present embodiment, as illustrated in FIG. 8, the insulating component 120 can include a supporting part 121 and a protecting part 122; an external surface of the supporting part 121 is concaved inwardly to form an accommodating part 1211 which is opened outwardly; the antenna 200 is disposed on the supporting part 121 and is located inside the accommodating part 1211. The supporting part 121 can be provided with a corresponding communication hole 1210, so that the signal line 117 can be connected with the antenna 200 through the communication hole 1210 in the supporting part 121 and meanwhile the signal line 117 can pass through the second hole part 115 to reach the internal surface 113 of the shielding component 110. The protecting part 122 covers the antenna 200 and the supporting part 121. By fixing the antenna 200 inside the accommodating part 1211 through the protecting part 122, a movement of the antenna 200 is limited. In the present embodiment, the protecting part 122 can be embedded at the accommodating part 1211 of the supporting part 121; a surface of the protecting part 122 far away from the receiving chamber, an external surface of the supporting part 121 far away from the receiving chamber, and an external surface 112 of the shielding component 110 are flush and connected with each other. Of course, the protecting part 122 can also cover and close the opening of the accommodating part 1211; in such case, the surface of the protecting part 122 facing the receiving chamber is abutted against the external surface of the supporting part 121, and the surface of the protecting part 122 far away from the receiving chamber is flush and connected with the external surface 112 of the shielding component 110.

In the present embodiment, a material of the supporting part 121 and a material of the protecting part 122 can be an insulating material such as mylar piece, plastic and rubber. Of course, the material of the supporting part 121 can also be insulating paint. For example, it's possible to coat the surface of the mounting hole 111 with insulating paint, and then arrange the antenna 200 at the first hole part 114 so as to achieve an insulation between the shielding component 110 and the antenna 200; subsequently, it's possible to cover the antenna 200 and the supporting part 121 with the protecting part 122 from above, so as to achieve positioning the antenna 200. Of course, the insulating component 120 can include the protecting part 122 only; and the antenna 200 is fixed on an internal surface of the protecting part 122. Theoretically, it only needs to coat the surface of the antenna 200 with insulating paint or to electrically insulate the antenna 200 from the shielding component 110 by other ways; in such case, the signal line can connect the antenna 200 with the element(s) located in the receiving chamber through the second hole part 115 and the first hole part 114.

Of course, the insulating component 120 can also be other functional module(s) such as fingerprint identification module. In such case, because a reserved space for accommodating the other functional module(s) is omitted, the thickness of the electronic apparatus can be reduced to some degrees, which facilitates a lighter and thinner structure.

The foregoing are merely specific embodiments of the present disclosure, but not limitative to the protection scope of the present disclosure. Within the technical scope disclosed by the present disclosure, any alternations or replacements which can be readily envisaged by one skilled in the art shall be within the protection scope of the present disclosure. Therefore, the protection scope of the invention shall be defined by the accompanying claims.

The present application claims the benefits of Chinese patent application No. 201821621803.9, which was filed on Sep. 30, 2018 and is fully incorporated herein by reference as part of the embodiments of this application.

What is claimed is:

1. A housing, comprising a shielding component and an insulating component fixedly connected with the shielding component, wherein
the insulating part is configured to arrange an antenna.

2. The housing according to claim 1, wherein the shielding component is provided with a through hole penetrating the shielding component, and
the insulating component is provided at the through hole.

3. The housing according to claim 2, wherein the through hole is configured to receive an antenna module comprising the insulating component and the antenna, and
the shielding component is configured to have a thickness greater than or equal to a thickness of the antenna module.

4. The housing according to claim 1, wherein
the shielding component comprises a first surface and a second surface opposite to each other, the shielding component is provided with a mounting hole, and the mounting hole comprises a first hole part and a second hole part,
the first hole part is concaved from the first surface towards the second surface of the shielding component to form an abutting surface, the second hole part penetrates both of the abutting surface and the second surface, and
the first hole part is configured to arrange the insulating component and the antenna, and the second hole part is configured such that a signal line connected with the antenna passes therethrough.

5. The housing according to claim 4, wherein the first hole part is configured to receive an antenna module comprising the insulating component and the antenna, and
the first hole part is configured to have a thickness greater or equal to a thickness of the antenna module.

6. The housing according to claim 4, wherein the insulating component comprises a supporting part and a protecting part,
one surface of the supporting part is concaved to form an accommodating part with an opening, the accommodating part is configured to receive the antenna, and
the supporting part is configured such that the signal line passes therethrough to be in contact with the second surface of the shielding component.

7. An electronic apparatus, comprising a housing and an antenna, wherein
the housing comprises a shielding component and an insulating component fixedly connected with the shielding component, and
the antenna is provided at the insulating part.

8. The electronic apparatus according to claim 7, wherein
the shielding component is provided with a through hole penetrating the shielding component, and
the insulating component is provided at the through hole.

9. The electronic apparatus to claim 8, wherein an antenna module comprising the insulating component and the antenna is located inside the through hole, and a thickness of the antenna module is smaller than or equal to a thickness of the shielding component.

10. The electronic apparatus according to claim 7, wherein
the antenna is connected with a signal line;
the shielding component comprises a first surface and a second surface opposite to each other, the shielding component is provided with a mounting hole, and the mounting hole comprises a first hole part and a second hole part,
the first hole part is concaved from the first surface towards the second surface of the shielding component to form an abutting surface, the second hole part penetrates both of the abutting surface and the second surface, and
the insulating component and the antenna are provided at the first hole part, and the signal line passes through the second hole part.

11. The electronic apparatus according to claim 10, wherein the antenna is located between the insulating component and the second hole part.

12. The electronic apparatus according to claim 11, wherein an antenna module comprising the insulating component and the antenna is located inside the first hole part, and a thickness of the antenna module is smaller than or equal to a thickness of the first hole part.

13. The electronic apparatus according to claim 10, wherein the insulating component comprises a supporting part and a protecting part,
one surface of the supporting part is concaved to form an accommodating part with an opening, the antenna is located on the supporting part and is located inside the accommodating part;
the signal line passes through the supporting part to be in contact with the second surface of the shielding component; and
the antenna is located between the protecting part and the supporting part.

14. The electronic apparatus according to claim 7, comprising a display module, wherein
at least one of the insulating component and the antenna is provided as a part of the display module.

15. The electronic apparatus according to claim 14, wherein the display module comprises a display screen and an electrode, and
at least part of the insulating component is provided as the display screen or is provided as at least part of the display screen.

16. The electronic apparatus according to claim 14, wherein the display module comprises a display screen and an electrode, and
at least part of the antenna is provided as the electrode or is provided as a part of the electrode or is located in a same layer with the electrode.

17. The electronic apparatus according to claim 7, wherein the housing is at least provided as a rear housing of the electronic apparatus.

18. The electronic apparatus according to claim 17, wherein the rear housing is provided with a protrusion part raised outwards with respect to an external surface of the rear housing, and an interior of the protrusion part is configured to receive one or more electronic element.

19. The electronic apparatus according to claim 18, wherein the protrusion part is provided with a heat dissipation hole.

20. The electronic apparatus according to claim 17, wherein the electronic apparatus is a display apparatus.
